(19) United States
(12) Patent Application Publication
(10) Pub. No.: US 2024/0053424 A1
(43) Pub. Date: Feb. 15, 2024

(54) MRI MAGNETIC FIELD CORRECTION DEVICE

(71) Applicants: UNIVERSITÉ D'AIX-MARSEILLE, Marseille (FR); CENTRE NATIONAL DE LA RECHERCHE SCIENTIFIQUE, Paris (FR); MULTIWAVE IMAGING SAS, Marseille (FR)

(72) Inventors: Tania del Socorro VERGARA-GOMEZ, Marseille (FR); Megdouda BENAMARA, Marseille (FR); Elodie GEORGET PARIS, Septemes les Vallons (FR); Redha ABDEDDAIM, Marseille (FR); Pierre JOMIN, Marseille (FR); Marc DUBOIS, Marseille (FR); Stefan ENOCH, Marseille (FR); Djamel BERRAHOU, Marseille (FR); Tryfon ANTONAKAKIS, Geneve (CH); Frank KOBER, Marseille (FR); David BENDAHAN, Maisons Alfort (FR)

(21) Appl. No.: 18/278,084

(22) PCT Filed: Feb. 11, 2022
(86) PCT No.: PCT/EP2022/053380

§ 371 Date: Aug. 21, 2023

(30) Foreign Application Priority Data
Feb. 23, 2021 (FR) FR2101730

(51) Int. Cl. G01R 33/565; G01R 33/28

(52) U.S. Cl. CPC G01R 33/5659; G01R 33/288

(57) ABSTRACT

A correction device for correcting a radio frequency magnetic field in magnetic resonance imaging, the device intended to be positioned on an area of a patient's body during a magnetic resonance imaging examination and including a substrate and at least one conductor track on the substrate, the at least one conductor track having at least two segments that are connected to each other by at least one reactive electrical component.

The present invention relates to a magnetic field correction device intended to be used for magnetic resonance imaging (MRI).

### TECHNICAL FIELD

The use of very powerful magnets to produce the static magnetic field B₀, required in MRI, allows a significant increase in the signal-to-noise ratio (SNR) of the measurement of the radiofrequency (RF) signal. This increase in the SNR results in a reduction in the time required to obtain images and in better spatial resolution.

Clinical MRI apparatuses, in particular with a magnetic field equal to 1.5 T or 3 T, are equipped with a volume antenna, called a “body antenna”, used to transmit the RF, i.e. radiofrequency, magnetic field, or B1+ field, of excitation to the nuclei that are to be studied. The purpose of this antenna is to produce a perfectly homogeneous signal in order to ensure the quality of the MRI images used by radiologists.

However, it is known that this homogeneity of the signal is not ensured during examination on large fields of view, that is to say greater than 30×30 cm², such as are implemented in particular in the context of MRI of the pelvis, heart or abdomen.

Other regions of the human body such as the joints (ankle, knee, wrist, elbow, shoulder) or the upper body (cervical and cranial regions) do not pose a problem with respect to the homogeneity of the RF magnetic field of excitation. However, it is of interest to improve the RF magnetic field reception modulus in order to receive a higher signal intensity. This increase in the signal permits an improvement in the spatial resolution of the images at a constant acquisition time or a reduction in the acquisition time for an identical spatial resolution.

### PRIOR ART

The U.S. Pat. No. 7,639,011 discloses an RF magnetic field distribution correction device configured for positioning on a patient in an MRI examination. This device comprises conductive dipole strips arranged in parallel on a support.

The application US 2015/196225 describes an antenna element for an MRI diagnostic tool to be placed under the breast, which may comprise a combination of conductor tracks and capacitors selected for an amplification of the RF magnetic field.

The application US 2011/137589 discloses a panel comprising current-conducting tracks for suppression of inhomogeneity in an RF magnetic field.

The application GB 2 580 011 discloses a device for concentrating a magnetic field of radiofrequency signals in an MRI system. The device comprises a plurality of conductive elements arranged in a matrix. The device can comprise semiconductors each connected between a pair of two conductive elements. These semiconductors require an external power supply.

The patent CN 102723608 discloses a metamaterial comprising microstructures disposed on a substrate. These microstructures comprise conductive wires forming open rings and inductance patches connected in series with the conductive wires.

The application US 2010/213941 discloses an antenna for exciting or detecting a magnetic resonance in an object to be examined. The antenna comprises at least one line resonator and a conductive loop interrupted by at least one capacitor. The document concerns an active system that is to be connected to a magnetic wave generation device.

There is a need to improve the acquisition of MRI images and to ensure their quality, particularly in the case of examinations carried out on large fields of view.

### DISCLOSURE OF THE INVENTION

Correction Device

According to a first aspect, the invention relates to a correction device for correcting a magnetic field in magnetic resonance imaging, said device being intended to be positioned on a region of a patient's body during a magnetic resonance imaging examination and comprising a substrate and at least one track disposed on the substrate, the at least one conductor track comprising at least two segments connected to each other by at least one reactive electrical component.

The invention makes it possible to solve the problems of homogenization of the radiofrequency magnetic field by use of a plane, fine and flexible structure which is perfectly compatible with the conditions of clinical examination in MRI. The reactive electrical components make it possible to correct the resonance frequency of the metal track or tracks and to reduce the quality factors of the resonances, and thus to modify the RF magnetic field produced during the MRI examination.

A “reactive electrical component” is to be understood as meaning that the component reacts to the passage of an electric current without power consumption or external power supply.

In the present invention, the device is not powered by a radiofrequency wave generation device and thus constitutes a passive system. During its operation, the device is traversed by a current created solely by a phenomenon of electromagnetic induction.

The invention also makes it possible to increase the signal-to-noise ratio of the MRI measurement in at least part of the human body without impacting the rest, while maintaining the specific absorption rate (SAR) below the authorized limit.

When it is worn by a patient during an MRI measurement using a transmission antenna and one or more reception arrays, the device according to the invention makes it possible to obtain an image with better contrast in the regions usually empty of a signal for MRIs with intense magnetic fields. These low-signal regions are found in particular in the case of pelvic, abdominal or cardiac MRI examinations, with a magnetic field at 3 T.

Reactive Electrical Component

The reactive electrical components are preferably capacitors.

In a variant, the reactive electrical components are inductors.

If the length of the segments to be connected is greater than or equal to the half wavelength of the MRI signal, the reactive electrical components are preferably capacitors. Otherwise, the reactive electrical components are preferably inductors.

In the case of a capacitor, the capacitance value of the capacitor is preferably between 1 pF and 1 nF.

In the case of an inductor, its value is preferably between 1 nH and 1 μH.

The choice of the capacitance of the capacitor(s) or of the inductor(s) is linked to the length of the segments placed end to end and to the number of segments.

The at least one reactive electrical component may have an electronically adjustable capacitance or inductance value, for example adjustable with the aid of a suitable electronic circuit.

The at least one reactive electrical component may be a surface-mounted component soldered to the conductor track at the adjacent ends of two segments of the track.

Tracks and Segments

The at least one conductor track comprises between one and fifteen segments. Increasing the number of segments makes it possible to control the distribution of the amplitude of the current flowing on the conductor track. This aspect makes it possible to adapt the size of the device according to the invention with respect to the targeted region.

Preferably, the segments are rectilinear and in alignment with one another.

The device may comprise several conductor tracks, in particular of elongate shape and arranged parallel to one another on the substrate. These tracks are preferably not interconnected.

All the conductor tracks can have the same length.

All the conductor tracks can comprise the same number of segments, in particular two segments.

The corresponding segments of the different conductor tracks preferably have the same length, the segments within the same conductor track being in particular of identical length. The term “corresponding segments” is to be understood as meaning the same N^{th} segment of the different metal tracks, N being an integer greater than 1 and less than the total number of segments of a metal track, counted according to the longitudinal axis along which each metal track extends.

The at least one conductor track is preferably made of a metal, preferably non-magnetic, in particular copper, silver or brass. In a preferred embodiment of the invention, the at least one conductor track is made of copper.

The device may comprise between one and thirty conductor tracks, in particular 15 tracks.

The width of the at least one track is preferably between 1 mm and 25 mm, being in particular equal to 12.5 mm.

The spacing between each conductor track, measured edge to edge, is preferably between 1 mm and 100 mm, being in particular equal to 50 mm.

The thickness of the at least one track is preferably between 0.005 mm and 0.2 mm.

The length of the at least one track is preferably between 0.1 m and 1 m, better still between 60 cm and 85 cm, being in particular equal to 70 cm.

Substrate

The thickness of the substrate is preferably between 0.01 mm and 1.6 mm, being in particular equal to 0.4 mm.

Preferably, the substrate is flexible. This ensures the flexibility of the entire device. The substrate can be made of a thermoplastic polymer, comprising in particular at least one epoxy resin composite or a polyimide, being in particular made of Kapton®. Preferably, the substrate is made of a low-loss material whose loss angle δ is such that tan(δ)<0.025.

Assembly

The invention also relates to an assembly comprising a device according to the invention and a protective cover, made in particular of a thermoplastic material, in particular a thermoplastic polymer, and intended to receive the device.

The cover may comprise a polymer-impregnated fabric compatible with safety and hygiene rules for healthcare and hospital applications.

Manufacturing Process

The invention also relates to a method of manufacturing a magnetic field correction device according to the invention and intended to be positioned on a region of a patient's body during a magnetic resonance imaging examination, in which method at least one conductor track is printed on a substrate, the at least one conductor track being cut into at least two segments connected to each other by at least one reactive electrical component.

The number of tracks, the number of segments, the width, length and/or thickness of the at least one track, the spacing between each conductor track, and/or the reactive electrical component(s), in particular the capacitance value in the case of a capacitor or capacitors, can be chosen according to the field of view of the region of the patient's body to be examined and/or the value of the static magnetic field implemented during the magnetic resonance imaging examination.

These choices determine the specific resonance frequency of the conductor track or tracks, which is advantageously fixed to be slightly higher, by a few percent, than the Larmor frequency used by MRI apparatuses, in particular an MRI scanner in the case of MRI imaging. The frequency used by the scanner can be determined beforehand: f₀=γ B₀ with f₀ the frequency, γ the gyromagnetic ratio of the nucleus (42.6 MHz/Tesla for example for hydrogen) and B₀ the intensity of the magnetic field of the scanner.

Digital simulation tools, for example that of electromagnetic field simulation by the finite element method, make it possible to optimize the aforementioned characteristics of the device according to the targeted regions of the body. Standard models of radiofrequency antennas and human bodies are used in these simulations. The use of the digital tool makes it possible to best describe the propagation of electromagnetic waves in the human body, which is a complex and heterogeneous environment.

Method of Use

The invention further relates to a method of use of a magnetic field correction device according to the invention, comprising the placement of at least one correction device on and/or under the region of the patient's body to be examined by magnetic resonance imaging.

The region can be the pelvic, abdominal, cardiac, cerebral or cervical region, or the joints, in particular the knee, the ankle, the elbow, the shoulder and the wrist.

A first correction device can be placed on the region of the patient's body to be examined, and a second correction device can be placed under the region of the patient's body to be examined. The reactive electrical component(s) of the first device may be different from the reactive electrical component(s) of the second device.

The intensity of the static magnetic field implemented during the magnetic resonance imaging examination can be equal to 1.5 T, 3 T and 7 T.

The characteristics set out above for the device apply to the methods, and vice versa.

### BRIEF DESCRIPTION OF THE DRAWINGS

The invention will be better understood on reading the following description and on examining the figures that accompany it. These figures are provided only as examples and do not in any way limit the invention.

FIG. 1 shows an example of a device according to the invention,

FIG. 2A shows the distribution of the B₁+ field obtained in a phantom M of a human simulation model by a body antenna without using the device according to the invention,

FIG. 2B shows the distribution of the B₁+ field of FIG. 2A in the case where the device shown in FIG. 1 has been used,

FIG. 3 illustrates an example of use of the device according to the invention,

FIG. 4A shows a sagittal section of the signal-to-noise ratio without use of the device according to the invention,

FIG. 4B shows the sagittal section of the signal-to-noise ratio from FIG. 4A in the case where the device shown in FIG. 1 has been used, and

FIG. 5 shows profiles of the signal-to-noise ratio taken on a horizontal line at the center of the images of FIGS. 4A and 4B.

### DETAILED DESCRIPTION

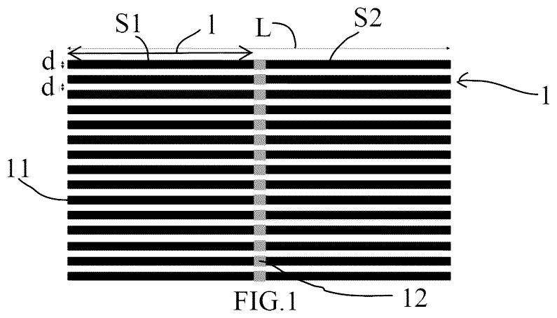

FIG. 1 illustrates an example of a device 1 according to the invention used for MRI examinations of the pelvic and abdominal regions, with a magnetic field equal to 3 T.

In the example illustrated, the device 1 comprises fifteen metal tracks 11, made of copper, of width w equal to 1.25 cm, spaced apart, edge to edge, by 1.25 cm, and of thickness equal to 0.01 cm. The tracks 11 have a length L equal to 70 cm.

These tracks 11 are cut into two segments S1, S2 connected to each other by fifteen reactive electrical components 12, namely capacitors of capacitance 10 pF in the example described.

In the example described, the tracks 11 are deposited on an FR-4 (Flame Resistant 4) resin substrate with a thickness equal to 0.04 cm. The device can be protected by a cover of suitable size, for example sewn and made of a thermoplastic polymer, in particular of Dartex.

Digital Study of Homogenization of the B₁+ Field

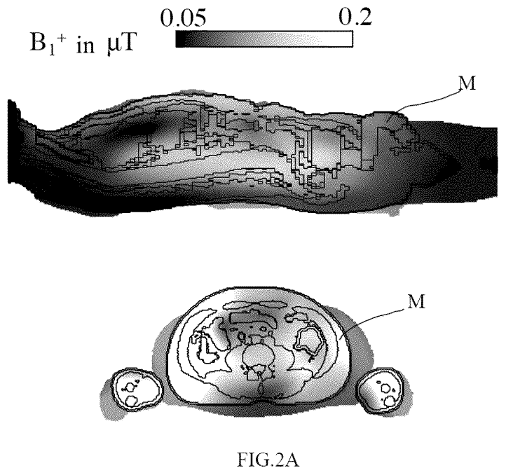

FIG. 2A shows the distribution of the B₁+ field obtained using a body antenna in a phantom M of a human simulation model at 128 MHz, corresponding to the Larmor frequency of the proton for a magnetic field equal to 3 T.

As is illustrated in FIG. 2A, the body antenna alone provides a non-homogeneous RF magnetic field, as can be seen from the dark regions showing low intensity.

Two correction devices according to the embodiment of FIG. 1 are then placed above and below the phantom M. As is illustrated in FIG. 2B, a marked improvement in the intensity and homogeneity of the B₁+ radiofrequency magnetic field is then observed.

The homogeneity of the B₁+ radiofrequency magnetic field makes it possible, on the one hand, to guarantee a homogeneous tilt angle throughout the observation region, which guarantees the homogeneity of the contrast in the final MRI images. The tilt angle is a parameter used during all the MRI acquisition sequences. It characterizes the angle formed by the average magnetization of the probed nuclei and the axis of the static magnetic field B₀. The value of the tilt angle is fixed by the amplitude and the duration of the radiofrequency pulses generated by the transmitting antenna.

On the other hand, the general increase in the intensity of the B₁+ radiofrequency magnetic field makes it possible to control the tilt angle with better efficacy, that is to say less power being supplied by the generator. This aspect is essential, for the patient, as regards electromagnetic safety, in terms of specific absorption rate, as presented in the table below.

Digital Study of the Specific Absorption Rate

The table below presents the study of the specific absorption rate (SAR) in three examples of use of a correction device according to FIG. 1: the “back” and “stomach” cases correspond to the unilateral use of a single correction device, and the “double” case corresponds to the combined use of two devices, as is shown in FIG. 2B. The “REFERENCE” column designates the reference case without a correction device according to the invention.

It will be noted in the three cases that, for identical input powers, the two SAR factors, either global, that is to say averaged over the whole of the phantom M, or local, that is to say averaged over 10 g of tissue, are reduced by the addition of one or two correction devices according to the invention.

TABLE 1

| | REFERENCE | Back | Stomach | Double |
|---|---|---|---|---|
| SAR global (mW/kg) | 15.8 | 15.1 | 15.6 | 15.6 |
| SAR 10 g local (mW/kg) | 147 | 125 | 129 | 111 |

Experimental Study of the Signal-to-Noise Ratio

The study of the signal-to-noise ratio is important for the quality of the final MRI images; a signal-to-noise ratio that is too low leads to the difficulty or impossibility of diagnosis by a physician. A significant increase in the signal-to-noise ratio also makes it possible to accelerate the measurement if high threshold levels are reached.

In the example described, the measurements are carried out on an MRI scanner with a magnetic field equal to 3 T using a phantom comprising a 20-L container with a size of 40×40×20 cm³ filled with water, representing an analog of a human abdomen. Signal transmission is performed by the body antenna of the MRI scanner, and signal reception is performed by two multi-channel antenna arrays, namely a dorsal array and a ventral array.

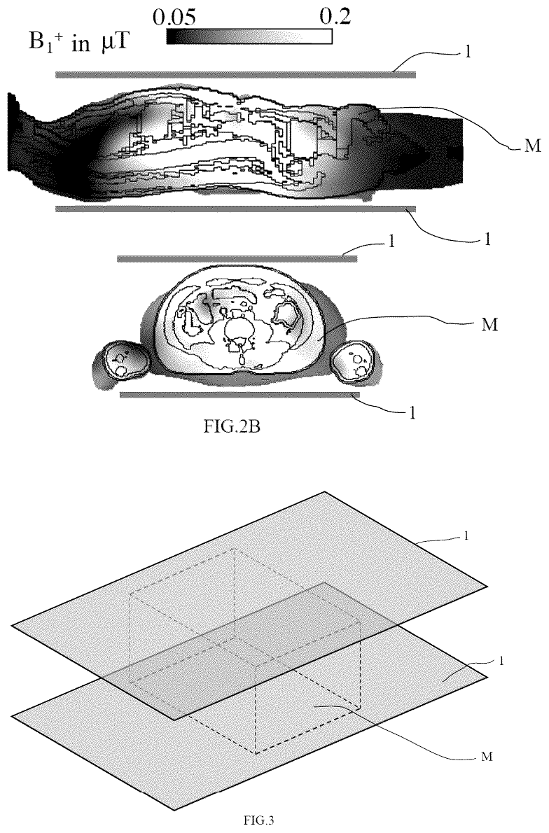

The study compares two measurements carried out respectively in a configuration not using a device according to the invention, corresponding to a reference measurement, and what is called a “double” configuration with two correction devices inserted between the reception arrays (not illustrated) and the surface of the phantom, as is illustrated in FIG. 3, in which the dotted volume shows the measurement region which contains the jerry can, and the shaded panels show the positioning of the two devices according to the invention, in contact with the measurement volume.

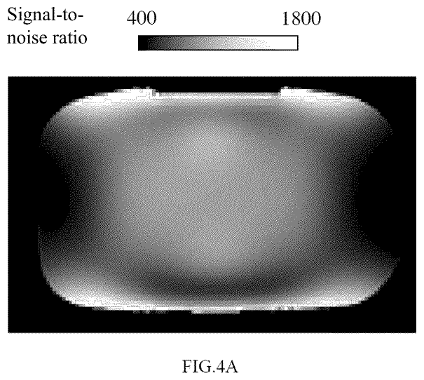

FIGS. 4A and 4B show the sagittal sections of the signal-to-noise ratios obtained.

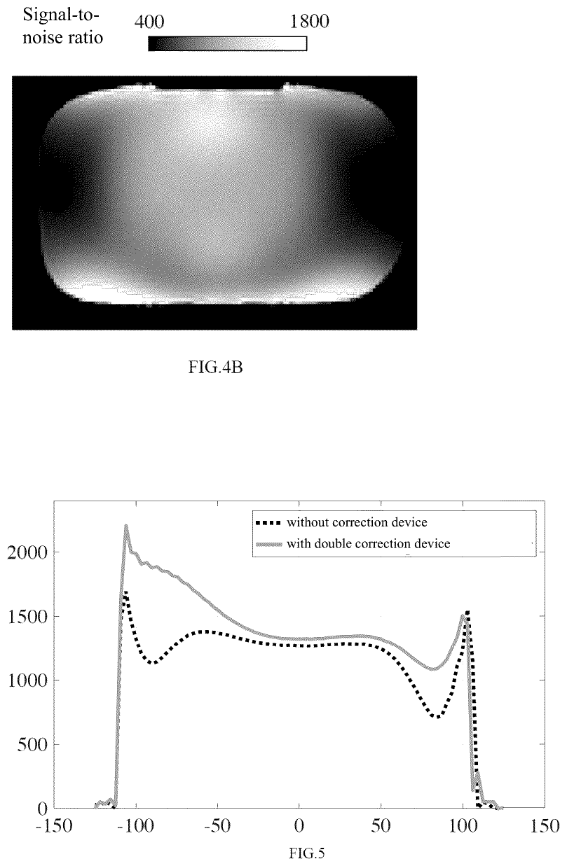

FIG. 5 shows a profile of the signal-to-noise ratio taken on a horizontal line at the center of the images from FIGS. 4A and 4B.

A marked improvement in the signal-to-noise ratio is observed along the whole profile and more generally throughout the section after insertion of the correction devices according to the invention.

The invention is not limited to the examples described above.

For example, other features for the tracks, the segments, the reactive electrical components and the substrate may be envisioned.

1. A correction device for correcting a radiofrequency magnetic field in magnetic resonance imaging, said device configured to be positioned on a region of a patient's body during a magnetic resonance imaging examination and comprising a substrate and several conductor tracks of elongate shape disposed parallel to each other on the substrate, each conductor track comprising at least two segments (S1; S2) connected to each other by at least one reactive electrical component.

2. The device as claimed in claim 1, wherein at least one reactive electrical component is a capacitor or an inductor.

3. The device as claimed in claim 1, wherein the at least one reactive electrical component is a capacitor, and the capacitance value of the capacitor is between 1 pF and 1 nF.

4. The device as claimed in claim 2, wherein the at least one reactive electrical component is an inductor with a value of between 1 nH and 1 μH.

5. The device as claimed in claim 1, wherein the at least one conductor track comprises between one and fifteen segments.

6. The device as claimed in claim 1, wherein the segments (S1; S2) are rectilinear and in alignment with one another.

7. The device as claimed in claim 1, wherein the at least one reactive electrical component is a surface-mounted component soldered to the conductor track at the adjacent ends of two segments (S1; S2) of the track.

8. The device as claimed in claim 1, wherein the device is not powered by a radiofrequency wave generation device and constitutes a passive system.

9. The device as claimed in claim 1, wherein all conductor tracks have the same length.

10. The device as claimed in claim 1, wherein all conductor tracks comprise the same number of segments (S1; S2).

11. The device as claimed in claim 1, wherein corresponding segments (S1; S2) of the different conductor tracks have the same length, the segments (S1; S2) within the same conductor track being in particular of identical length.

12. The device as claimed in claim 1, wherein the at least one conductor track is made of a metal, in particular of copper.

13. The device as claimed in claim 1, wherein the substrate is made of a thermoplastic polymer, comprising in particular at least one composite of epoxy resin or a polyimide.

14. An assembly comprising the device of claim 1 and a protective cover intended to receive the device, the protective cover being made in particular of a thermoplastic material, in particular a thermoplastic polymer.

15. A method of manufacturing a radiofrequency magnetic field correction device as claimed in claim 1 and intended to be positioned on a region of a patient's body during a magnetic resonance imaging examination, in which method at least one conductor track is printed on a substrate, the at least one conductor track being cut into at least two segments (S1; S2) connected to each other by at least one reactive electrical component.

16. A method of use of a radiofrequency magnetic field correction device as claimed in claim 1, comprising the placement of at least one correction device on and/or under the region of the patient's body to be examined by magnetic resonance imaging.

17. The method of use as claimed in claim 16, the region being in particular the pelvic, abdominal, cardiac, cerebral or cervical region, or the joints, in particular the knee, the ankle, the elbow, the shoulder or the wrist.

18. The method of use as claimed in claim 17, in which a first correction device is placed on the region of the patient's body to be examined, and a second correction device is placed under the region of the patient's body to be examined, the reactive electrical component(s) of the first device being different from the reactive electrical component(s) of the second device.

19. The method of use as claimed in claim 16, in which the intensity of the static magnetic field implemented during the magnetic resonance imaging examination is equal to 1.5 T, 3 T or 7 T.
